(19) United States
(12) Patent Application Publication
(10) Pub. No.: US 2022/0309989 A1
(43) Pub. Date: Sep. 29, 2022

(54) GATE DRIVER ON ARRAY DEVICE AND DISPLAY PANEL

(71) Applicant: Wuhan China Star Optoelectronics Technology Co., Ltd., Wuhan, Hubei (CN)

(72) Inventor: Yongxiang ZHOU, Wuhan, Hubei (CN)

(73) Assignee: Wuhan China Star Optoelectronics Technology Co., Ltd., Wuhan, Hubei (CN)

(21) Appl. No.: 17/058,759

(22) PCT Filed: Sep. 24, 2020
(86) PCT No.: PCT/CN2020/117298

§ 371 Date: Nov. 25, 2020

(30) Foreign Application Priority Data
Sep. 4, 2020 (CN) 202010919048.8

(51) Int. Cl. G09G 3/20; G06V 40/13

(52) U.S. Cl. CPC G09G 3/2092; G06V 40/13; G09G 2300/0408; G09G 2310/08; G09G 2300/0876; G09G 2300/0426; G09G 2310/0267; G09G 2360/14

(57) ABSTRACT

A gate driver on array (GOA) device and a display panel are provided. The GOA device includes multi-level cascaded GOA units. Each level of the GOA units comprises a first sub GOA unit and a second sub GOA unit. The first sub GOA unit is configured to output a first scan driving signal. The second sub GOA unit is configured to output a second scan driving signal. The first sub GOA unit and the second sub GOA unit share at least a portion of signal wirings, so that a width of the GOA device is narrowed while a circuit layout of the display panel is simplified.

### FIELD OF INVENTION

The present disclosure relates to the field of display field, and more particularly, to a gate driver on array (GOA) device and a display panel.

### BACKGROUND OF INVENTION

Gate driver on array (GOA) technology integrates a gate drive circuit onto an array substrate of a display panel, thereby omitting the gate drive integrated circuit part, so as to reduce the product costs in terms of material cost and manufacturing process cost.

In order to control normal display of the display panel, a set of display driving GOA devices are arranged near two edges of display areas in an existing display panel. In order to achieve a fingerprint recognition function of the display panel, it is necessary to install a set of fingerprint-driven GOA devices near two edges of the display panel, which results in a GOA having a large width. It is difficult to narrow a bezel of the display panel.

Therefore, it is necessary to provide a novel GOA device and a display panel to solve the above technical problems.

### SUMMARY OF INVENTION

### Technical Problems

The present disclosure provides a GOA device and a display panel for solving the problems that the existing display panel adopts a set of fingerprint-driven GOA devices and a set of display-driven GOA devices on both sides of the display area, resulting in a GOA having a large width and a bezel of the display panel bezel that is difficult to narrow down.

### Technical Solutions

The present application provides a gate driver on array (GOA) device, comprising multi-level cascaded GOA units, each level of the GOA units comprising a first sub GOA unit and a second sub GOA unit;

wherein the first sub GOA unit is configured to output a first scan driving signal, the second sub GOA unit is configured to output a second scan driving signal, and the first sub GOA unit and the second sub GOA unit share at least a portion of signal wirings; and

wherein the first scan driving signal is a display scan driving signal, and the second scan driving signal is a fingerprint scan driving signal.

In the GOA device provided by the present disclosure, the first sub GOA unit and the second sub GOA unit share at least one of a forward-scanning signal wiring, a backward-scanning signal wiring, a constant-voltage high-level signal wiring, a constant-voltage low-level signal wiring, or a clock signal wiring.

In the GOA device provided by the present disclosure, the forward-scanning signal wiring, the backward-scanning signal wiring, the constant-voltage high-level signal wiring, the constant-voltage low-level signal wiring, and the clock signal wiring are positioned between the first sub GOA unit and the second sub GOA unit.

In the GOA device provided by the present disclosure, the first sub GOA unit comprises at least a first sub output module, a first sub pull-down module, and a first sub function control module, and the second sub GOA unit comprises at least a second sub output module, a second sub pull-down module, and a second sub function control module;

wherein the first sub output module is connected to the constant-voltage low-level signal and the constant-voltage high-level signal, and is electrically connected to a first node and a third clock control terminal for outputting the first scan driving signal at a present level;

wherein the first sub pull-down module is connected to at least the constant-voltage low-level signal and the constant-voltage high-level signal, and is electrically connected to at least a fourth clock control terminal, the first node, and the first scan driving signal at a present level for pulling down potentials of both the first node and the first scan driving signal at the present level to a potential of the constant-voltage low-level signal;

wherein the first sub function control module is connected to a first function control signal and a second function control signal, and is electrically connected to the first node, a second node, and the first scan driving signal at the present level for implementing a turn-on function and a turn-off function of all the first scan driving signals of the GOA device;

wherein the second sub output module is connected to the constant-voltage low-level signal and the constant-voltage high-level signal, and the second sub output module is electrically connected to a third node and the third clock control terminal for outputting the second scan driving signal at the present level;

wherein the second sub pull-down module is connected to at least the constant-voltage low-level signal and the constant-voltage high-level signal, and is electrically connected to at least the fourth clock control terminal, the third node, and the second scan driving signal at the present level for pulling down potentials of both the third node and the second scan driving signal at the present level to the potential of the constant-voltage low-level signal;

wherein the second sub function control module is connected to a fourth function control signal and a fifth function control signal, and is electrically connected to the third node, a fourth node, and the second scan driving signal at the present level for implementing the turn-on function and the turn-off function of all the second scan driving signals of the GOA device.

In the GOA device provided by the present disclosure, the first sub output module comprises a seventh transistor, a ninth transistor, and a first capacitor, and the second sub output module comprises a twenty-seventh transistor, a twenty-nineth transistor, and a fourth capacitor;

wherein a gate of the seventh transistor is connected to the constant-voltage high-level signal, a source of the seventh transistor is electrically connected to the first node, and a drain of the seventh transistor is electrically connected to a gate of the ninth transistor;

wherein a source of the ninth transistor is electrically connected to the third clock control terminal, and a drain of the ninth transistor is electrically connected to the first scan driving signal at the present level;

wherein one end of the first capacitor is electrically connected to the first node, and another end of the first capacitor is electrically connected to the constant-voltage low-level signal;

wherein a gate of the twenty-seventh transistor is connected to the constant-voltage high-level signal, a source of the twenty-seventh transistor is electrically connected to the third node, and a drain of the twenty-seventh transistor is electrically connected to a gate of the twenty-ninth transistor;

wherein a source of the twenty-ninth transistor is electrically connected to the third clock control terminal, and a drain of the twenty-ninth transistor is electrically connected to the second scan driving signal at the present level; and

wherein one end of the fourth capacitor is electrically connected to the third node, and another end of the fourth capacitor is electrically connected to the constant-voltage low-level signal.

In the GOA device provided by the present disclosure, the first sub GOA unit further comprises a first sub forward-backward scanning module, and the second sub GOA unit further comprises a second sub forward-backward scanning module;

wherein the first sub forward-backward scanning module is connected to the first scanning driving signal at a previous level, a forward scanning signal, the first scanning driving signal at a next level, the backward scanning signal, and the constant-voltage low-level signal, and is electrically connected to the first node and the second node for outputting the forward scanning signal to the first node or for outputting the backward scanning signal to the first node, and outputting the constant-voltage low-level signal to the second node under control of a potential of the first node;

wherein the second sub forward-backward scanning module is connected to the second scanning driving signal at the previous level, the forward scanning signal, the second scanning driving signal of the next level, the backward scanning signal and the constant-voltage low-level signal, and is electrically connected to the third node and the fourth node for outputting the forward scanning signal to the third node, or for outputting the backward scanning signal to the third node, and outputting the constant-voltage low-level signal to the fourth node under control of the potential of the third node.

In the GOA device provided by the present disclosure, the first sub scanning module comprises a first transistor, a second transistor, and a sixth transistor, and the second sub scanning module comprises a twenty-first transistor, a twenty-second transistor, and a twenty-sixth transistor;

wherein a gate of the first transistor is connected to the first scan driving signal at the previous level, a source of the first transistor is connected to the forward scanning signal, and a drain of the first transistor is electrically connected to the first node and a gate of the sixth transistor;

wherein a gate of the second transistor is connected to the first scan driving signal at the next level, a source of the second transistor is connected to the backward scanning signal, and a drain of the second transistor is electrically connected to the gate of the sixth transistor;

wherein a source of the sixth transistor is connected to the constant-voltage low-level signal, and a drain of the sixth transistor is electrically connected to the second node;

wherein a gate of the twenty-first transistor is connected to the second scan driving signal at the previous level, a source of the twenty-first transistor is connected to the forward scanning signal, and a drain of the twenty-first transistor electrically connected to the third node and a gate of the twenty-sixth transistor;

wherein a gate of the twenty-second transistor is connected to the second scan driving signal at the next level, a source of the twenty-second transistor is connected to the backward scanning signal, and a drain of the twenty-second transistor is electrically connected to the gate of the twenty-sixth transistor; and

wherein a source of the twenty-sixth transistor is connected to the constant-voltage low-level signal, and a drain of the twenty-sixth transistor is electrically connected to the fourth node.

In the GOA device provided by the present disclosure, the first sub pull-down module comprises a third transistor, a fourth transistor, a fifth transistor, an eighth transistor, a tenth transistor, and a second capacitor, the second sub pull-down modules comprise a twenty-third transistor, a twenty-fourth transistor, a twenty-fifth transistor, a twenty-eighth transistor, a thirtieth transistor, and a fifth capacitor;

wherein a gate of the third transistor is connected to the forward scanning signal, a source of the third transistor is connected to the fourth clock control terminal, a gate of the fourth transistor is connected to the backward scanning signal, a source of the fourth transistor is connected to a second clock control terminal, and a drain of the third transistor and a drain of the fourth transistor are connected to a gate of the eighth transistor;

wherein a source of the eighth transistor is connected to the constant-voltage high-level signal; a drain of the eighth transistor, a gate of the fifth transistor, and a gate of the tenth transistor are electrically connected to the second node; a source of the fifth transistor and a source of the tenth transistor are connected to the constant-voltage low-level signal; a drain of the fifth transistor is electrically connected to the first node; and a drain of the tenth transistor is electrically connected to the first scan driving signal at the present level;

wherein one end of the second capacitor is electrically connected to the second node, and another end of the second capacitor is electrically connected to the constant-voltage low-level signal;

wherein a gate of the twenty-third transistor is connected to a forward scanning signal, a source of the twenty-third transistor is connected to the fourth clock control terminal, a gate of the twenty-fourth transistor is connected to the backward scanning signal, a source of the twenty-fourth transistor is connected to the second clock control terminal, a drain of the twenty-third transistor and a drain of the twenty-fourth transistor are connected to a gate of the twenty-eighth transistor;

wherein a source of the twenty-eighth transistor is connected to the constant-voltage high-level signal; a drain of the twenty-eighth transistor, a gate of the twenty-fifth transistor, and a gate of the thirtieth transistor are electrically connected to the fourth node; a source of the twenty-fifth transistor and a source of the thirtieth transistor are connected to the constant-voltage low-level signal, a drain of the twenty-fifth transistor is electrically connected to the third node; and a drain of the thirtieth transistor is electrically connected to the second scan driving signal at the present level; and

wherein one end of the fifth capacitor is electrically connected to the fourth node, and another end of the fifth capacitor is electrically connected to the constant-voltage low-level signal.

In the GOA device provided by the present disclosure, the first sub function control module comprises an eleventh transistor, a twelfth transistor, and a thirteenth transistor, and the second sub function control module comprises a thirty-first transistor, a thirty-second transistor, and a thirty-third transistor;

wherein a source and of the eleventh transistor, a gate of the eleventh transistor, and a gate of the twelfth transistor are connected to the first function control signal, a drain of the eleventh transistor and a drain of the thirteenth transistor are connected to the first scan driving signal at the present level, a source of the twelfth transistor and a source of the thirteenth transistor are connected to the constant-voltage low-level signal, a drain of the twelfth transistor is electrically connected to the second node, and a gate of the thirteenth transistor is connected to the second function control signal;

wherein a source of the thirty-first transistor, a gate of the thirty-first transistor, and a gate of the thirty-second transistor are connected to the fourth function control signal, a drain of the thirty-first transistor and a drain of the thirty-third transistor are connected to the second scan driving signal at the present level, a source of the thirty-second transistor and a source of the thirty-third transistor are connected to the constant-voltage low-level signal, a drain of the thirty-second transistor is electrically connected to the fourth node, and a gate of the thirty-third transistor is connected to the fifth function control signal.

In the GOA device provided by the present disclosure, the first sub GOA unit and the second sub GOA unit comprise a turn-on functional phase and a turn-off functional phase;

in response to the first sub GOA unit in the turn-on functional phase, the first function control signal is a high-level signal, and the second function control signal is a low-level signal;

in response to the first sub GOA unit in the turn-off functional phase, the first function control signal is a low-level signal and the second function control signal is a high-level signal;

in response to the second sub GOA unit in the turn-on functional phase, the fourth function control signal is a high-level signal and the fifth function control signal is a low-level signal; and

in response to the second sub GOA unit in the turn-off functional phase, the fourth function control signal is a low-level signal and the fifth function control signal is a high-level signal.

In the GOA device provided by the present disclosure, the first sub GOA unit further comprises a third sub function control module, and the second sub GOA unit further comprises a fourth sub function control module;

wherein the third sub control module is connected to the third function control signal, the first scan driving signal at a previous level, and the constant-voltage low-level signal, the third sub control module is electrically connected to the first node and the second node for outputting the third function control signal to the first node, and for outputting the constant-voltage low-level signal to the second node under control of a potential of the first node, and for implementing the turn-off function of all the first scan driving signals of the GOA device;

wherein the fourth sub function control module is connected to a sixth function control signal, the second scan driving signal at the previous level, and the constant-voltage low-level signal; the fourth sub function control module is electrically connected to the third node for outputting the sixth function control signal to the third node, and for outputting the constant-voltage low-level signal to the fourth node under control of the potential of the third node, and for interpermeating the turn-off function of all the second scan driving signals of the GOA device.

In the GOA device provided by the present disclosure, the third sub function control module comprises a fourteenth transistor and a fifteenth transistor, and the fourth sub function control module comprises a thirty-fourth transistor and a thirty-fifth transistor;

wherein a gate of the fourteenth transistor is connected to the first scan driving signal at the previous level, a source of the fourteenth transistor is connected to the third function control signal, and a drain of the fourteenth transistor is electrically connected to the first node and a gate of the fifteenth transistor;

wherein a gate of the fifteenth transistor is electrically connected to the first node, a source of the fifteenth transistor is connected to the constant-voltage low-level signal, and a drain of the fifteenth transistor is electrically connected to the second node;

wherein a gate of the thirty-fourth transistor is connected to the second scan driving signal at the previous level, a source of the thirty-fourth transistor is connected to the sixth function control signal, and a drain of the thirty-fourth transistor is electrically connected to the third node and a gate of the thirty-fifth transistor; and

wherein a gate of the thirty-fifth transistor is electrically connected to the third node, a source of the thirty-fifth transistor is connected to the constant-voltage low-level signal, and a drain of the thirty-fifth transistor is electrically connected to the fourth node.

In the GOA device provided by the present disclosure, the first sub pull-down module comprises a sixteenth transistor, a seventeenth transistor, an eighteenth transistor, and a third capacitor, and the second sub pull-down module comprises a thirty-sixth transistor, a thirty-seventh transistor, a thirty-eighth transistor, and a sixth capacitor;

wherein a gate of the sixteenth transistor is electrically connected to the second node, a source of the sixteenth transistor is connected to the constant-voltage low-level signal; a drain of the sixteenth transistor is electrically connected to the first node; a gate of the seventeenth transistor is connected to the clock signal at the next level; a source of the seventeenth transistor is connected to the first function control signal; a drain of the seventeenth transistor is electrically connected to the second node; a gate of the eighteenth transistor is electrically connected to the second node; a source of the eighteenth transistor is connected to the constant-voltage low-level signal; a drain of the eighteenth transistor is electrically connected to the first scan driving signal at the present level; one end of the third capacitor is electrically connected to the second node; and another end of the third capacitor is electrically connected to the constant-voltage low-level signal;

wherein a gate of the thirty-sixth transistor is electrically connected to the fourth node, a source of the thirty-sixth transistor is connected to the constant-voltage low-level signal; a drain of the thirty-sixth transistor is electrically connected to the third node; a gate of the thirty-seventh transistor is connected to the clock signal at the next level; a source of the thirty-seventh transistor is connected to the fourth function control signal; a drain of the thirty-seventh transistor is electrically connected to the fourth node; a gate of the thirty-eighth transistor is electrically connected to the fourth node; a source of the thirty-eighth transistor is connected to the constant-voltage low-level signal; a drain of the eighteenth transistor is electrically connected to the second scan driving signal at the present level; one end of the sixth capacitor is electrically connected to the fourth node; and another end of the sixth capacitor is electrically connected to the constant-voltage low-level signal.

In the GOA device provided by the present disclosure, the first sub function control module comprises a seventeenth transistor and a nineteenth transistor, and the second sub function control module comprises a thirty-seventh transistor and a thirty-nineth transistor;

wherein a gate of the nineteenth transistor is connected to the second function control signal, a source of the nineteenth transistor is connected to the constant-voltage low-level signal, and a drain of the nineteenth transistor is connected to the first scan driving signal at the present level; and

wherein a gate of the thirty-ninth transistor is connected to the fifth function control signal, a source of the thirty-ninth transistor is connected to the constant-voltage low-level signal, and a drain of the thirty-ninth transistor is connected to the second scan driving signal at the present level.

In the GOA device provided by the present disclosure, the GOA device receives a first clock signal, a second clock signal, a third clock signal, and a fourth clock signal; and

wherein the first clock signal, the second clock signal, the third clock signal, and the fourth clock signal are valid in sequence within a time division of an action cycle of the GOA device.

The present disclosure further provides a display panel, comprising a GOA device and a functional display layer on the GOA device.

In the display panel provided by the present disclosure, the display panel further comprises a fingerprint recognition GOA circuit;

wherein a first sub GOA unit of the GOA device is configured to output a first scan driving signal to implement normal display of the display panel; and

wherein the second sub GOA unit of the GOA device is configured to output a second scan driving signal and control a reset function and/or a reading function of the fingerprint recognition GOA circuit to implement a fingerprint recognition function of the display panel.

In the display panel provided by the present disclosure, the second sub GOA unit simultaneously controls the reset function and/or the reading function of multiple rows of the fingerprint recognition GOA circuit.

In the display panel provided by the present disclosure, the second sub GOA unit of the GOA device is positioned on a side of the GOA device close to a display area.

In the display panel provided by the present disclosure, the display panel comprises a display area, wherein the GOA device comprises an odd-level cascaded GOA sub circuit and an even-level cascaded GOA sub circuit; and

wherein the odd-level cascaded GOA sub circuit and the even-level cascaded GOA sub circuit are positioned on both sides of the display area.

### Beneficial Effects

In the present disclosure, the first sub GOA unit and the second sub GOA unit share at least a portion of signal wirings, so that the GOA device is able to implement a display scan driving function and a fingerprint scan driving function while a circuit layout of the display panel is simplified. The space occupied by the GOA device of the display panel is reduced, and the width of the GOA device is narrowed, which facilitates narrowing the bezel of the display panel.

### DESCRIPTION OF DRAWINGS

The technical solution, as well as beneficial advantages, of the present invention will become apparent in the following detailed description of an embodiment of the present invention, with reference to the accompanying drawings.

FIG. 1 is a schematic diagram of a signal wiring distribution of a GOA device of the present disclosure.

FIG. 2 is a schematic diagram of a first structure of the GOA device of the present disclosure.

FIG. 3 is a schematic diagram of a second structure of the GOA device of the present disclosure.

FIG. 4 is a schematic diagram of a first structure of a first sub GOA unit of the present disclosure.

FIG. 5 is a schematic diagram of a second structure of the first sub GOA unit of the present disclosure.

FIG. 6 is a timing diagram of the GOA device of the present disclosure.

FIG. 7 is a schematic structural diagram of the GOA circuit of the display panel of the present disclosure.

FIG. 8 is a schematic structural diagram of a fingerprint-driven GOA circuit of the display panel of the present disclosure.

### DETAILED DESCRIPTION OF PREFERRED EMBODIMENTS

The present disclosure provides a GOA device and a display panel. In order to make purposes, technical solutions, and effects of the application to be clear and more specific, the present disclosure is further described with reference to the drawings and examples. It is to be understood that the specific embodiments described herein are only used to explain the present disclosure, and are not intended to limit the present disclosure.

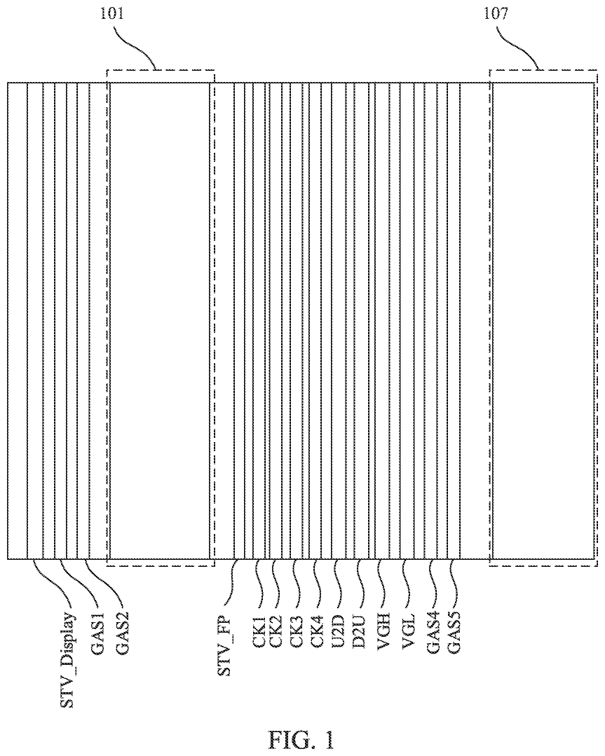

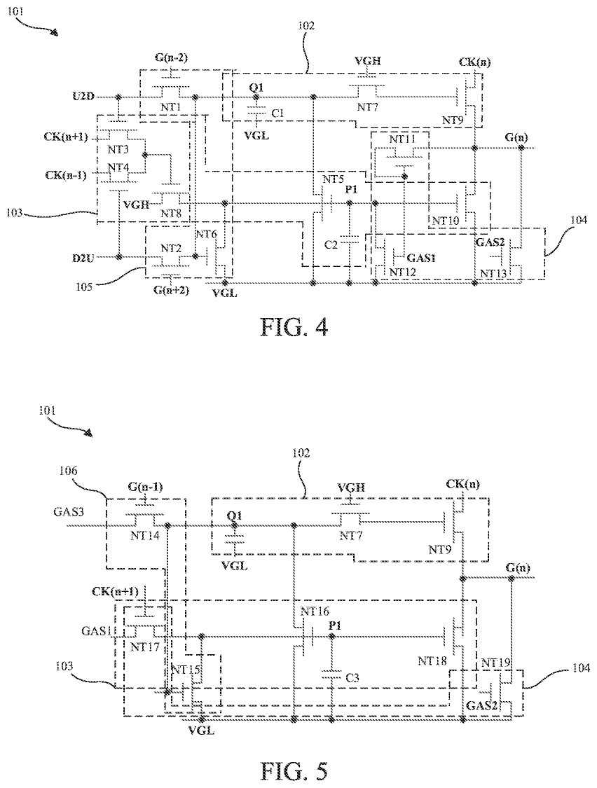

Please refer to FIGS. 1-6. The present disclosure provides a GOA device 100, including multi-level cascaded GOA units.

The GOA device 100 is configured for outputting a scan driving signal. The driving scanning signal includes a display driving scanning signal and a fingerprint scan driving signal.

The GOA units include a plurality of signal wirings, a plurality of transistors, and a plurality of capacitors.

Each level of the GOA units may include a first sub GOA unit 101 and a second sub GOA unit 107. The first sub GOA unit 101 and the second sub GOA unit 107 may share at least a portion of the signal wirings.

The first scan driving signal is a display scan driving signal. The second scan driving signal is a fingerprint scan driving signal.

In the present embodiment, configurations of the transistors and the capacitors of the first sub GOA unit 101 can be same as those of the second sub GOA unit 107, i.e., an architecture of the first sub GOA unit 101 and an architecture of the second sub GOA unit 107 can be the same.

In the present embodiment, the first sub GOA unit 101 and the second sub GOA unit 107 share at least one of a forward-scanning signal wiring, backward-scanning signal wiring, a constant-voltage high-level signal wiring, a constant-voltage low-level signal wiring, or clock signal wiring of the GOA device 100.

Please refer to FIG. 1. When the first sub GOA unit 101 and the second sub GOA unit 107 share a forward scanning signal U2D, a backward scanning signal D2U, a constant-voltage high-level signal VGH, a constant-voltage low-level signal VGL, and signal wirings of the clock signals CK1-CK4, the above-mentioned signal wirings are arranged between the first sub GOA unit 101 and the second sub GOA unit 107.

In the present embodiment, in addition to the forward scanning signal U2D, the backward scanning signal D2U, the constant-voltage high-level signal VGH, the constant-voltage low-level signal VGL, and the signal routing of the clock signals CK1-CK4, other signal wirings of the first sub GOA unit, such as a turn-on signal of a display scanning driver STV_Display, a first function control signal GAS1, a second function control signal GAS2, etc., may be positioned on a side of the first sub GOA unit 101 away from the second sub GOA unit 107.

In the present embodiment, in addition to the forward scanning signal U2D, the backward scanning signal D2U, the constant-voltage high-level signal VGH, the constant-voltage low-level signal VGL, and the signal routing of the clock signals CK1-CK4, other signal wirings of the second sub GOA unit 107, such as a turn-on signal STV_FP for a fingerprint scanning driver, the fourth function control signal GAS4, the fifth function control signal GAS5, etc., may be positioned between the first sub GOA unit 101 and the second sub GOA unit 107.

Owing to the configurations of the first sub GOA unit 101 and the second sub GOA unit 107, the GOA device 100 can achieve functions of outputting display driving scanning signals and fingerprint scan driving signals using the same GOA device. Moreover, the first sub GOA unit 101 and the second sub GOA unit 107 can share a portion of the signal wiring, for example, the forward-scanning signal wiring, the backward-scanning signal wiring, the constant-voltage high-level signal wiring, the constant-voltage low-level signal wiring, and the clock signal wiring. The total number of signal wirings of the GOA devices near two edges of the display area of the display panel can be reduced, which is beneficial to reduce the width of the GOA and achieve the narrow bezel design of the display panel.

The first sub GOA unit 101 is used for outputting a first scan driving signal. The second sub GOA unit 107 is used for outputting a second scan driving signal. The first scan driving signal may be a display scan driving signal, and the second scan driving signal may be a fingerprint scan driving signal.

In the present embodiment, when the GOA device 100 is in a first working phase, a n-th level first sub GOA unit 101 can be used for outputting a n-th level first scan driving signal to charge a corresponding n-th scanning line in the display area, so as to achieve normal display of the display panel. When the GOA device 100 is in a second working phase, a m-th level second sub GOA unit 107 is used for outputting a m-th level second scan driving signal to control reset or reading of a corresponding m-th fingerprint identification module of the display area, so as to achieve the fingerprint identification of the display panel.

In the present embodiment, the GOA device 100 may include an odd-level cascaded GOA sub circuit and an even-level cascaded GOA sub circuit.

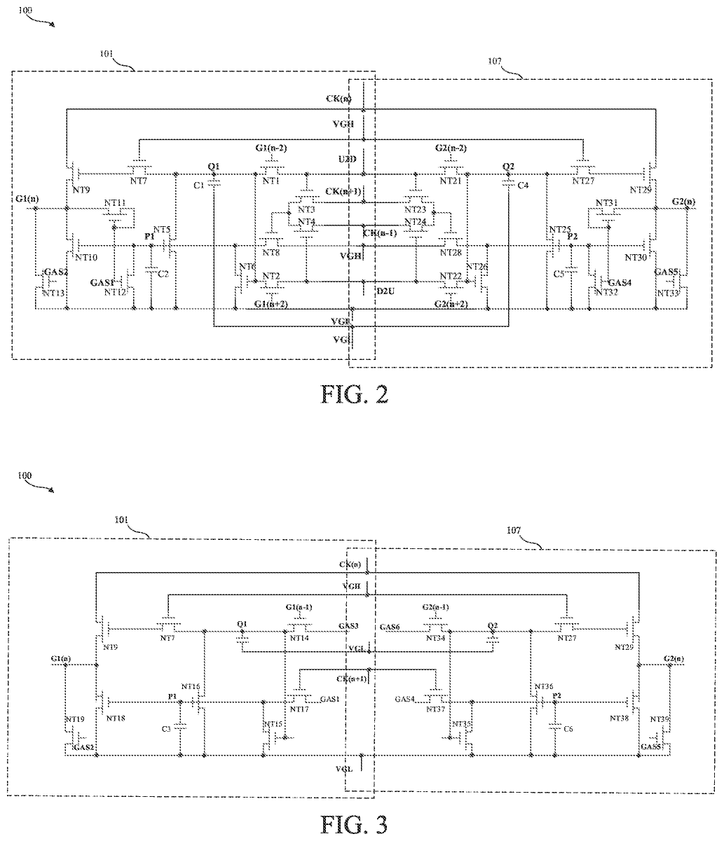

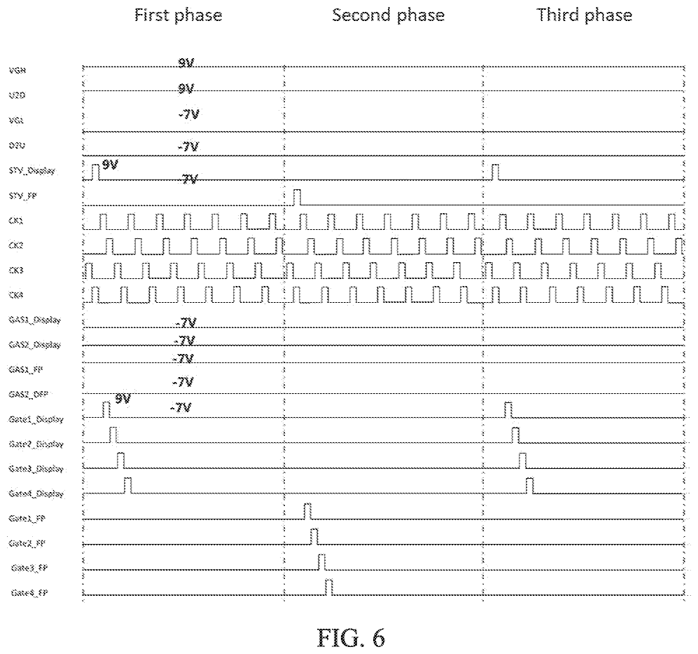

Please refer to FIG. 2 and FIG. 6. In the present embodiment, the GOA device 100 can receive the first clock signal CK1, the second clock signal CK2, the third clock signal CK3, and the fourth clock signal CK4. The first clock signal CK1, the second clock signal CK2, the third clock signal CK3, and the fourth clock signal CK4 are valid in sequence within a time division of an action cycle of the GOA device 100.

When the n-th level clock signal of the n-th level GOA unit is the first clock signal CK1, a n+1th level clock signal of the n-th level GOA unit is the second clock signal CK2, and the n−1th level clock signal of the n-th level GOA unit is the fourth clock signal CK4.

For example, in a level 1+4k GOA unit, the second clock control terminal CK(n−1) is connected to the fourth clock signal CK4, the third clock control terminal CK(n) is connected to the first clock signal CK1, and the fourth clock control terminal CK(n+1) is connected to the second clock signal CK2, where k is a positive integer.

In a 2+4k level GOA unit, the second clock control terminal CK(n−1) is connected to the first clock signal CK1, the third clock control terminal CK(n) is connected to the second clock signal CK2, and the fourth clock control terminal CK(n+1) is connected to the third clock signal CK3, where k is a positive integer.

In the 3+4k level GOA unit, the second clock control terminal CK(n−1) is connected to the second clock signal CK2, the third clock control terminal CK(n) is connected to the third clock signal CK3, and the fourth clock control terminal CK(n+1) is connected to the fourth clock signal CK4, where k is a positive integer.

In a 4+4k level GOA unit, the second clock control terminal CK(n−1) is connected to the third clock signal CK3, the third clock control terminal CK(n) is connected to the fourth clock signal CK4, and the fourth clock control terminal CK(n+1) is connected to the first clock signal CK1, where k is a positive integer.

Please refer to FIG. 6, which is a timing diagram applied to the display panel when the GOA device 100 is a 4CK architecture. The STV_Display is the turn-on signal of the display scanning driver, which can be inputted from a gate of the first thin-film transistor of the first sub GOA unit 101 at the first level. STV_FP is the turn-on signal of the fingerprint scanning driver, which can be input from a gate of the twenty-first thin-film transistor of the second sub GOA unit 107 at the first level. The first phase is a displaying phase, the second phase is the fingerprint reset phase, and the third level is the fingerprint reading phase. GAS1_Display is the first function control signal and GAS2_Display is the second function control signal. When the display panel is working normally, the first function control signal and the second function control signal are low-level signals. GAS1_FP is the fourth function control signal and GAS2_DFP is the fifth function control signal. When the display panel is working normally, the fourth function control signal and the fifth function control signal are low-level signals. GATE1_Display to GATE4_Display represent the first display scan driving signal to the fourth display scan driving signals, which correspond to the gate driving signals of the first sub GOA unit 101 at the first level to the fourth level. GATE1_FP to GATE4_FP represent the first fingerprint scan driving signal to the fourth fingerprint scan driving signal, which correspond to the gate driving signals of the first level to the fourth level of the second sub GOA unit 107. During the first phase to the third phase, the clock signals CK1 to CK4 are continuously performing pulse output. When the display panel performs normal display, fingerprint reading, and fingerprint reset, the forward scanning signal and constant-voltage high-level signal are kept constant at 9 volts, and the constant-voltage low-level signal and the backward scanning signal are kept constant at −7 volts.

In the present embodiment, a number of scanning rows of the first sub GOA unit 101 and a number of scanning rows of the second sub GOA unit 107 may be the same or different. Clock periods and durations of the first phase to the third phase can be adjusted accordingly, so as to increase working performance of the GOA device 100.

Please refer to FIG. 2 and FIG. 3. The first sub GOA unit 101 may include at least a first sub output module 102, a first sub pull-down module 103, and a first sub function control module 104.

The second sub GOA unit 107 includes at least a second sub output module, a second sub pull-down module, and a second sub function control module.

In the present embodiment, the first sub output module 102 is connected to the constant-voltage low-level signal and the constant-voltage high-level signal, and is electrically connected to a first node and a third clock control terminal CK(n) for outputting the first scan driving signal at a present level. The second sub output module is connected to the constant-voltage low-level signal and the constant-voltage high-level signal, and the second sub output module is electrically connected to a third node and the third clock control terminal CK(n) for outputting the second scan driving signal at the present level.

In the present embodiment, the first sub pull-down module 103 is connected to at least the constant-voltage low-level signal and the constant-voltage high-level signal, and is electrically connected to at least a fourth clock control terminal CK(n+1), the first node, and the first scan driving signal at a present level for pulling down potentials of both the first node and the first scan driving signal at the present level to a potential of the constant-voltage low-level signal. The second sub pull-down module is connected to at least the constant-voltage low-level signal and the constant-voltage high-level signal, and is electrically connected to at least the fourth clock control terminal CK(n+1), the third node, and the second scan driving signal at the present level for pulling down potentials of both the third node and the second scan driving signal at the present level to the potential of the constant-voltage low-level signal

In the present embodiment, the first sub function control module 104 is connected to a first function control signal and a second function control signal, and is electrically connected to the first node, a second node, and the first scan driving signal at the present level for implementing a turn-on function and a turn-off function of all the first scan driving signals of the GOA device 100. The second sub function control module is connected to a fourth function control signal and a fifth function control signal, and is electrically connected to the third node, a fourth node, and the second scan driving signal at the present level for implementing the turn-on function and the turn-off function of all the second scan driving signals of the GOA device 100.

Please refer to FIG. 2. In the present embodiment, the first sub GOA unit 101 further includes a first sub forward-backward scanning module 105. The first sub forward-backward scanning module 105 is connected to the first scanning driving signal at a previous level, a forward scanning signal, the first scanning driving signal at a next level, the backward scanning signal, and the constant-voltage low-level signal, and is electrically connected to the first node and the second node for outputting the forward scanning signal to the first node or for outputting the backward scanning signal to the first node, and outputting the constant-voltage low-level signal to the second node under control of a potential of the first node.

In the present embodiment, the second sub GOA unit 107 further includes a second sub forward-backward scanning module. The second sub forward-backward scanning module is connected to the second scanning driving signal at the previous level, the forward scanning signal, the second scanning driving signal of the next level, the backward scanning signal, and the constant-voltage low-level signal, and is electrically connected to the third node and the fourth node for outputting the forward scanning signal to the third node, or for outputting the backward scanning signal to the third node, and outputting the constant-voltage low-level signal to the fourth node under control of the potential of the third node.

In the present embodiment, both the forward scanning signal and the backward scanning signal may be direct current (DC) power sources. A potential of the forward scanning signal and a potential of the backward scanning signal may be opposite. When the GOA device 100 performs a forward scanning, the forward scanning signal is a high-level signal and the reverse scanning signal is a low-level signal. When the GOA device 100 performs backward scanning, the forward scanning signal is a low-level signal and the reverse scanning signal is a high-level signal.

Please refer to FIG. 3. In the present embodiment, the first sub GOA unit 101 may not be provided with the first sub forward-backward scanning module 105. In this case, the first sub GOA unit 101 may include a third sub function control module 106. The third sub function control module 106 is connected to the third function control signal, the first scan driving signal at a previous level, and the constant-voltage low-level signal, the third sub control module is electrically connected to the first node and the second node for outputting the third function control signal to the first node, and for outputting the constant-voltage low-level signal to the second node under control of a potential of the first node, and for implementing the turn-off function of all the first scan driving signals of the GOA device 100.

Please refer to FIG. 3. Similarly, the second sub GOA unit 107 may not be provided with the second sub forward-backward scanning module. In this case, the fourth sub function control module 107 is connected to a sixth function control signal, the second scan driving signal at the previous level, and the constant-voltage low-level signal. The fourth sub function control module is electrically connected to the third node for outputting the sixth function control signal to the third node, and for outputting the constant-voltage low-level signal to the fourth node under control of the potential of the third node, and for interpermeating the turn-off function of all the second scan driving signals of the GOA device 100.

In the foregoing embodiment, the first sub GOA unit 101 and the second sub GOA unit 107 have the same or similar architectural configuration. The following mainly takes the configuration of each modules of the first sub GOA unit 101 as an example to explain the technical solution of the present disclosure.

Please refer to FIGS. 2-5. In the present embodiment, the first sub output module 102 includes a seventh transistor NT7, a ninth transistor NT9, and a first capacitor C1.

A gate of the seventh transistor NT7 is connected to a constant-voltage high-level signal VGH, a source of the seventh transistor NT7 is electrically connected to the first node Q1, and a drain of the seventh transistor NT7 is electrically connected to a gate of the ninth transistor NT9.

A source of the ninth transistor NT9 is electrically connected to the third clock control terminal CK(n) and a drain of the ninth transistor NT9 is electrically connected to the first scan driving signal G1(n) at the present level.

One end of the first capacitor C1 is electrically connected to the first node Q1, and another end of the first capacitor C1 is electrically connected to the constant-voltage low-level signal VGL.

In the present embodiment, the second sub output module includes a twenty-seventh transistor NT27, a twenty-ninth transistor NT29, and a fourth capacitor C4.

A gate of the twenty-seventh transistor NT27 is connected to the constant-voltage high-level signal VGH. A source of the twenty-seventh transistor NT27 is electrically connected to the third node Q2, and a drain of the twenty-seventh transistor NT27 is electrically connected to a gate of the twenty-ninth transistor NT29.

A source of the twenty-ninth transistor NT29 is electrically connected to the third clock control terminal CK(n), and a drain of the twenty-ninth transistor NT29 is electrically connected to the second scan driving signal G2(n) at the present level.

One end of the fourth capacitor C4 is electrically connected to the third node Q2, and another end of the fourth capacitor C4 is electrically connected to the constant-voltage low-level signal VGL.

In the present embodiment, the first sub scanning module 105 may include a first transistor NT1, a second transistor NT2, and a sixth transistor NT6.

A gate of the first transistor NT1 is connected to the first scan driving signal at the previous level G1(n−2), a source of the first transistor NT1 is connected to the forward scanning signal U2D, and a drain of the first transistor NT1 is electrically connected to the first node Q1 and a gate of the sixth transistor NT6.

A gate of the second transistor NT2 is connected to the first scan driving signal G1(n+2) at the next level, a source of the second transistor NT2 is connected to the backward scanning signal D2U, and a drain of the second transistor NT2 is electrically connected to the gate of the sixth transistor NT6.

A source of the sixth transistor NT6 is connected to the constant-voltage low-level signal VGL, and a drain of the sixth transistor NT6 is electrically connected to the second node P1.

In the present embodiment, the second sub scanning module may include a twenty-first transistor NT21, a twenty-second transistor NT22, and a twenty-sixth transistor NT26.

A gate of the twenty-first transistor NT21 is connected to the second scan driving signal at the previous level G2(n−2), a source of the twenty-first transistor NT21 is connected to the forward scanning signal U2D, and a drain of the twenty-first transistor NT21 electrically connected to the third node Q2 and a gate of the twenty-sixth transistor NT26.

A gate of the twenty-second transistor NT22 is connected to the second scan driving signal at the next level G2(n+2), a source of the twenty-second transistor NT22 is connected to the backward scanning signal D2U, and a drain of the twenty-second transistor NT22 is electrically connected to the gate of the twenty-sixth transistor NT26.

A source of the twenty-sixth transistor NT26 is connected to the constant-voltage low-level signal VGL, and a drain of the twenty-sixth transistor NT26 is electrically connected to the fourth node P2.

In the present embodiment, when the first sub GOA unit 101 includes the first sub forward-backward scanning module 105, the first sub pull-down module 103 includes a third transistor NT3, a fourth transistor NT4, and a fifth transistor NT5, the eighth transistor NT8, the tenth transistor NT10, and the second capacitor C2.

A gate of the third transistor NT3 is connected to the forward scanning signal U2D, a source of the third transistor NT3 is connected to the fourth clock control terminal CK(n+1), a gate of the fourth transistor is connected to the backward scanning signal U2D, a source of the fourth transistor NT4 is connected to a second clock control terminal CK(n−1), and a drain of the third transistor NT3 and a drain of the fourth transistor NT4 are connected to a gate of the eighth transistor NT8.

A source of the eighth transistor NT8 is connected to the constant-voltage high-level signal VGH. A drain of the eighth transistor NT8, a gate of the fifth transistor NT5, and a gate of the tenth transistor NT10 are electrically connected to the second node P1. A source of the fifth transistor NT5 and a source of the tenth transistor NT10 are connected to the constant-voltage low-level signal VGL. A drain of the fifth transistor NT5 is electrically connected to the first node Q1. A drain of the tenth transistor NT10 is electrically connected to the first scan driving signal at the present level G1(n).

One end of the second capacitor C2 is electrically connected to the second node P1. Another end of the second capacitor C2 is electrically connected to the constant-voltage low-level signal VGL.

In the present embodiment, when the second sub GOA unit 107 includes the second sub forward-backward scanning module, the second sub pull-down module includes a twenty-third transistor NT23, a twenty-fourth transistor NT24, and a twenty-fifth transistor NT25, the twenty-eighth transistor NT28, the thirtieth transistor NT30, and the fifth capacitor C5.

A gate of the twenty-third transistor NT23 is connected to a forward scanning signal U2D, a source of the twenty-third transistor NT23 is connected to the fourth clock control terminal CK(n+1), a gate of the twenty-fourth transistor NT24 is connected to the backward scanning signal D2U, a source of the twenty-fourth transistor NT24 is connected to the second clock control terminal CK(n−1), a drain of the twenty-third transistor NT23 and a drain of the twenty-fourth transistor NT24 are connected to a gate of the twenty-eighth transistor NT28.

A source of the twenty-eighth transistor NT28 is connected to the constant-voltage high-level signal VGH. A drain of the twenty-eighth transistor NT28, a gate of the twenty-fifth transistor NT25, and a gate of the thirtieth transistor NT30 are electrically connected to the fourth node Q2. A source of the twenty-fifth transistor NT25 and a source of the thirtieth transistor NT30 are connected to the constant-voltage low-level signal VGL. A drain of the twenty-fifth transistor NT25 is electrically connected to the third node Q3. A drain of the thirtieth transistor NT30 is electrically connected to the second scan driving signal G2(n) at the present level.

One end of the fifth capacitor C5 is electrically connected to the fourth node P2. Another end of the fifth capacitor C5 is electrically connected to the constant-voltage low-level signal VGL.

In the present embodiment, when the first sub GOA unit 101 includes the first sub scanning module 105, the first sub function control module 104 includes an eleventh transistor NT11, a twelfth transistor NT12, and the thirteenth transistor NT13.

A source and of the eleventh transistor NT11, a gate of the eleventh transistor NT11, and a gate of the twelfth transistor NT12 are connected to the first function control signal GAS1, a drain of the eleventh transistor NT11 and a drain of the thirteenth transistor NT13 are connected to the first scan driving signal G1(n) at the present level, a source of the twelfth transistor NT12 and a source of the thirteenth transistor NT13 are connected to the constant-voltage low-level signal VGL, a drain of the twelfth transistor NT12 is electrically connected to the second node P2, and a gate of the thirteenth transistor NT13 is connected to the second function control signal GAS2.

In the present embodiment, the first sub GOA unit 101 and the second sub GOA unit both include a turn-on functional phase and a turn-off functional phase.

In the present embodiment, when the first sub function control module 104 is used for the turn-on function of all the first scan driving signals, the first function control signal GAS1 is a high-level signal and the second function control signal GAS2 is a low-level signal. When the first sub function control module 104 is used for the turn-off functional phase of all the first scan driving signals GAS1, the first function control signal GAS1 is a low-level signal, and the second function control signal GAS2 is a high-level signal. When the GOA device 100 does not require all the first scan drive signals to be turned on or all the first drive signals to be turned off, the first scan driving signals GAS1 and the second function control signal GAS2 are low-level signals.

In the present embodiment, when the second sub GOA unit 107 includes the second sub scanning module, and the second sub function control module includes a thirty-first transistor NT31, a thirty-second transistor NT32, and a thirty-third transistor NT33.

A source of the thirty-first transistor NT31, a gate of the thirty-first transistor NT31, and a gate of the thirty-second transistor NT32 are connected to the fourth function control signal GAS4. A drain of the thirty-first transistor NT31 and a drain of the thirty-third transistor NT33 are connected to the second scan driving signal G2(n) at the present level. A source of the thirty-second transistor NT32 and a source of the thirty-third transistor NT33 are connected to the constant-voltage low-level signal VGL. A drain of the thirty-second transistor NT32 is electrically connected to the fourth node Q2. A gate of the thirty-third transistor NT33 is connected to the fifth function control signal GAS5.

In the present embodiment, when the second sub function control module is used for the turn-on functions of all the second scan driving signal, the fourth function control signal GAS4 is a high-level signal and the fifth function control signal GAS5 is a low-level signal. When the second sub function control module is used for the turn-off function of all the second scan driving signals, the fourth function control signal GAS4 is a low-level signal, and the fifth function control signal GAS5 is a high-level signal. When the GOA device 100 does not require all the second scan driving signals to be turned on or all the second scan driving signals to be turned off, the fourth function control signal GAS4 and the fifth function control signal GAS5 is a low-level signal.

In the present embodiment, when the first sub GOA unit 101 includes the third sub function control module 106, the third sub function control module 106 includes a fourteenth transistor NT14 and a fifteenth transistor NT15. A gate of the fourteenth transistor NT14 is connected to the first scan driving signal G1(n−1) at the previous level, a source of the fourteenth transistor NT15 is connected to the third function control signal GAS3, and a drain of the fourteenth transistor NT14 is electrically connected to the first node P1 and a gate of the fifteenth transistor NT15.

A gate of the fifteenth transistor NT15 is electrically connected to the first node Q1, a source of the fifteenth transistor NT15 is connected to the constant-voltage low-level signal VGL, and a drain of the fifteenth transistor NT15 is electrically connected to the second node P1.

In the present embodiment, when the second sub GOA unit 107 includes the fourth sub function control module, the fourth sub function control module includes a thirty-fourth transistor NT34 and a thirty-fifth transistor NT35.

A gate of the thirty-fourth transistor NT34 is connected to the second scan driving signal at the previous level G2(n−1), a source of the thirty-fourth transistor NT34 is connected to the sixth function control signal GAS6, and a drain of the thirty-fourth transistor NT34 is electrically connected to the third node Q2 and a gate of the thirty-fifth transistor NT35.

A gate of the thirty-fifth transistor NT35 is electrically connected to the third node Q2, a source of the thirty-fifth transistor NT35 is connected to the constant-voltage low-level signal VGL, and a drain of the thirty-fifth transistor NT35 is electrically connected to the fourth node P2.

In the present embodiment, the constructions of the transistors and the capacitors of the first sub output module 102 in the case that the first sub GOA unit 101 includes the third sub function control module 106 can be the same as or similar to the constructions of the transistors and the capacitors of the first sub output module 102 in case that the first sub GOA unit 101 includes the first sub forward-backward scanning module 105, which are not be repeatedly described herein.

In the present embodiment, the constructions of the transistors and the capacitors of the second sub output module in the case that the second sub GOA unit 107 includes the fourth sub function control module can be the same as or similar to the constructions of the transistors and the capacitors of the second sub output module in case that the second sub GOA unit 107 includes the first sub forward-backward scanning module, which are not be repeatedly described herein.

In the present embodiment, when the first sub GOA unit 101 includes the third sub function control module 106, the first sub pull-down module 103 may include a sixteenth transistor NT16, a seventeenth transistor NT17, an eighteen transistors NT18, and a third capacitor C3.

A gate of the sixteenth transistor NT16 is electrically connected to the second node P1, a source of the sixteenth transistor is connected to the constant-voltage low-level signal VGL. A drain of the sixteenth transistor NT16 is electrically connected to the first node Q1. A gate of the seventeenth transistor NT17 is connected to the clock signal at the next level CK(n+1). A source of the seventeenth transistor NT18 is connected to the first function control signal GAS1. A drain of the seventeenth transistor NT17 is electrically connected to the second node P1. A gate of the eighteenth transistor NT18 is electrically connected to the second node P1. A source of the eighteenth transistor NT18 is connected to the constant-voltage low-level signal VGL. A drain of the eighteenth transistor NT18 is electrically connected to the first scan driving signal G1(n) at the present level. One end of the third capacitor C3 is electrically connected to the second node P1. Another end of the third capacitor C3 is electrically connected to the constant-voltage low-level signal VGL.

In the present embodiment, when the second sub GOA unit 107 includes the fourth sub function control module, the second sub pull-down module may include a thirty-sixth transistor NT36, a thirty-seventh transistor NT37, a third Eighteen transistors NT38, and a sixth capacitor C6.

A gate of the thirty-sixth transistor NT36 is electrically connected to the fourth node Q2, a source of the thirty-sixth transistor NT36 is connected to the constant-voltage low-level signal VGL. A drain of the thirty-sixth transistor NT36 is electrically connected to the third node Q2. A gate of the thirty-seventh transistor NT37 is connected to the clock signal CK(n+1) at the next level. A source of the thirty-seventh transistor NT37 is connected to the fourth function control signal GAS4. A drain of the thirty-seventh NT37 transistor is electrically connected to the fourth node P2. A gate of the thirty-eighth NT38 transistor is electrically connected to the fourth node P2. A source of the thirty-eighth transistor NT38 is connected to the constant-voltage low-level signa VGL. A drain of the eighteenth transistor NT38 is electrically connected to the second scan driving signal G2(n) at the present level. One end of the sixth capacitor C6 is electrically connected to the fourth node P2. Another end of the sixth capacitor C6 is electrically connected to the constant-voltage low-level signal VGL.

In the present embodiment, when the first sub GOA unit 101 includes the third sub function control module 106, the first sub function control module 104 may include a seventeenth transistor NT17 and a nineteenth transistor NT19.

A gate of the nineteenth transistor NT19 is connected to the second function control signal GAS2, a source of the nineteenth transistor NT19 is connected to the constant-voltage low-level signal VGL, and a drain of the nineteenth transistor NT19 is connected to the first scan driving signal at the present level G(n).

In the present embodiment, when the first sub GOA unit 101 performs a normal level transfer, the third function control signal GAS3 is a constant-voltage high-level signal.

When the GOA device 100 requires all the first scan driving signals to be turned off, the third function control signal GAS3 is a low-level signal. At this time, the second function control signal GAS2 is also a high-level signal and turns on the nineteenth thin-film transistor NT19.

In the present embodiment, when the second sub GOA unit 107 performs normal level transfer, the fourth function control signal GAS4 is a constant-voltage high-level signal.

When the GOA device 100 requires all the first scan driving signals to be turned on, the first function control signal GAS1 is a low-level signal. At this time, the gate of the seventeenth transistor NT17 is connected to the clock signal CK(n+1) at the next level and becomes a high-level signal, so that all the first scan driving signals are turned on.

In the present embodiment, when the second sub GOA unit 107 includes the fourth sub function control module, the second sub function control module may include a thirty-seventh transistor NT37 and a thirty-ninth transistor NT39.

A gate of the thirty-ninth transistor NT39 is connected to the fifth function control signal GAS5, a source of the thirty-ninth transistor NT39 is connected to the constant-voltage low-level signal VGL, and a drain of the thirty-ninth transistor NT39 is connected to the second scan driving signal G2(n) at the present level.

In the present embodiment, when the second sub GOA unit 107 performs a normal level transfer, the sixth function control signal GAS6 is a constant-voltage high-level signal.

When the GOA device 100 requires all the second scan driving signals to be turned off, the sixth function control signal GAS6 is a low-level signal. At this time, the fifth function control signal GAS5 is also a high-level signal and turns on the thirty-ninth thin-film transistor NT39.

In the present embodiment, when the second sub GOA unit 107 performs a normal level transfer, the fourth function control signal GAS4 is a constant-voltage high-level signal.

When the GOA device 100 requires all the second scan driving signals to be turned on, the fourth function control signal GAS4 is a low-level signal. At this time, a gate of the thirty-seventh transistor NT37 is connected to the clock signal CK(n+1) at the next level and becomes a high-level signal, so that all the second scan driving signals are turned on.

In the GOA device 100 provided in the present application, the first sub GOA unit 101 and the second sub GOA unit 107 share at least a portion of the signal wiring, for example, the forward-scanning signal wiring. The GOA device is able to implement a display scan driving function and a fingerprint scan driving function while a circuit layout of the display panel is simplified. The space occupied by the GOA device 100 of the display panel is reduced and the width of the GOA device 100 is narrowed, which facilitates narrowing the bezel of the display panel.

The present disclosure also proposes a display panel, which includes the GOA device as described above and a functional display layer positioned on the GOA device 100.

The display panel further includes a fingerprint recognition GOA circuit 108. The second sub GOA unit of the GOA device 100 is configured to control the reset and/or reading functions of the fingerprint recognition GOA circuit 108 to achieve the fingerprint recognition function of the display panel.

In the present embodiment, the second sub GOA unit can simultaneously control the reset and/or read functions of multiple rows of the fingerprint identification GOA circuit 108, which is beneficial to reduce a width of the GOA device 100.

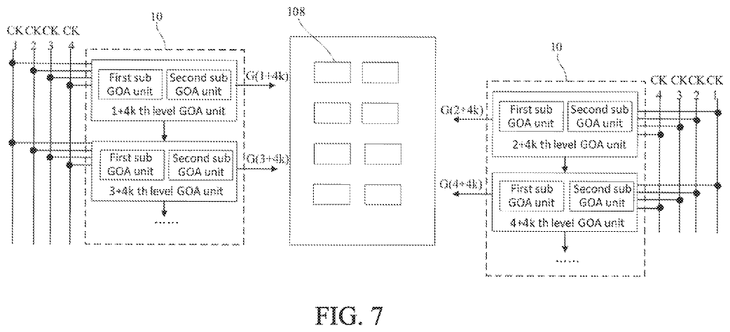

Please refer to FIG. 7. In the present embodiment, the GOA device 100 may include an odd-level cascaded GOA sub circuit 10 and an even-level cascaded GOA sub circuit 10.

In the present embodiment, the fingerprint recognition GOA circuit 108 may be positioned in the display area of the display panel. The GOA sub circuit formed by the odd-level cascaded GOA units 10 of the GOA device may be positioned near one edge of the display area. The GOA sub circuit formed by cascading the even-level cascaded GOA sub circuit 10 of the GOA device may be positioned near the other edge of the display area. The second sub GOA unit may be positioned on an edge of the GOA device close to the display area.

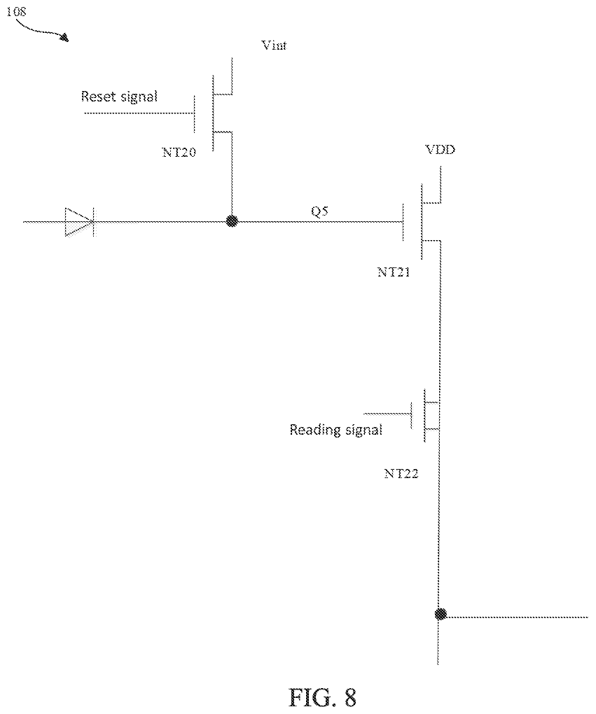

Please refer to FIG. 8. In the present embodiment, the twentieth transistor is configured to reset the fingerprint recognition GOA circuit. Vint is a direct current (DC) signal. When the reset signal is inputted, the reset signal is a high potential signal. The transistor is turned on, so that the fifth node is at a fixed voltage. The twenty-first transistor and twenty-second transistor are used to read the fingerprint recognition GOA circuit. VDD is a DC signal. During fingerprint recognition, because reflectance of a valley and reflectance of a ridge of the fingerprint to light are different, different fingerprint recognition GOA circuits produce different photo-generated currents through photodiodes, and the fifth nodes have different potentials. In different fingerprint recognition GOA circuits, the fifth nodes have different potentials which result in different currents. Therefore, the display panel achieves fingerprint recognition.

The present disclosure proposes a GOA device and a display panel. The GOA device includes multi-level cascaded GOA units. Each level of the GOA units includes a first sub GOA unit and a second sub GOA unit. The first sub GOA unit is used for the output of the first scan driving signal. The second sub GOA unit is used for the output of the second scan driving signal. The first sub GOA unit and the second sub GOA unit share at least a portion of the signal wiring. The first scan driving signal is a display scan driving signal and the second scan driving signal is a fingerprint scan driving signal. In the present disclosure, the first sub GOA unit 101 and the second sub GOA unit 107 share at least a portion of the signal wiring. The GOA device is able to implement a display scan driving function and a fingerprint scan driving function while a circuit layout of the display panel is simplified. The space occupied by the GOA device 100 of the display panel is reduced and the width of the GOA device 100 is narrowed, which facilitates narrowing the bezel of the display panel.

Understandably, one of ordinarily skill in the art can carry out equivalent modifications and changes to the described embodiment according to technical solutions and technical concepts of the present application, and all such modifications and changes are considered encompassed in the scope of protection defined by the claims of the present application.

1. A gate driver on array (GOA) device, comprising multi-level cascaded GOA units, each level of the GOA units comprising a first sub GOA unit and a second sub GOA unit;
wherein the first sub GOA unit is configured to output a first scan driving signal, the second sub GOA unit is configured to output a second scan driving signal, and the first sub GOA unit and the second sub GOA unit share at least a portion of signal wirings; and
wherein the first scan driving signal is a display scan driving signal, and the second scan driving signal is a fingerprint scan driving signal.

2. The GOA device according to claim 1, wherein the first sub GOA unit and the second sub GOA unit share at least one of a forward-scanning signal wiring, a backward-scanning signal wiring, a constant-voltage high-level signal wiring, a constant-voltage low-level signal wiring, or a clock signal wiring.

3. The GOA device according to claim 2, wherein the forward-scanning signal wiring, the backward-scanning signal wiring, the constant-voltage high-level signal wiring, the constant-voltage low-level signal wiring, and the clock signal wiring are positioned between the first sub GOA unit and the second sub GOA unit.

4. The GOA device according to claim 2, wherein the first sub GOA unit comprises at least a first sub output module, a first sub pull-down module, and a first sub function control module, and the second sub GOA unit comprises at least a second sub output module, a second sub pull-down module, and a second sub function control module;
wherein the first sub output module is connected to the constant-voltage low-level signal and the constant-voltage high-level signal, and is electrically connected to a first node and a third clock control terminal for outputting the first scan driving signal at a present level;
wherein the first sub pull-down module is connected to at least the constant-voltage low-level signal and the constant-voltage high-level signal, and is electrically connected to at least a fourth clock control terminal, the first node, and the first scan driving signal at a present level for pulling down potentials of both the first node and the first scan driving signal at the present level to a potential of the constant-voltage low-level signal;
wherein the first sub function control module is connected to a first function control signal and a second function control signal, and is electrically connected to the first node, a second node, and the first scan driving signal at the present level for implementing a turn-on function and a turn-off function of all the first scan driving signals of the GOA device;
wherein the second sub output module is connected to the constant-voltage low-level signal and the constant-voltage high-level signal, and the second sub output module is electrically connected to a third node and the third clock control terminal for outputting the second scan driving signal at the present level;
wherein the second sub pull-down module is connected to at least the constant-voltage low-level signal and the constant-voltage high-level signal, and is electrically connected to at least the fourth clock control terminal, the third node, and the second scan driving signal at the present level for pulling down potentials of both the third node and the second scan driving signal at the present level to the potential of the constant-voltage low-level signal;
wherein the second sub function control module is connected to a fourth function control signal and a fifth function control signal, and is electrically connected to the third node, a fourth node, and the second scan driving signal at the present level for implementing the turn-on function and the turn-off function of all the second scan driving signals of the GOA device.

5. The GOA device according to claim 4, wherein the first sub output module comprises a seventh transistor, a ninth transistor, and a first capacitor, and the second sub output module comprises a twenty-seventh transistor, a twenty-nineth transistor, and a fourth capacitor;
wherein a gate of the seventh transistor is connected to the constant-voltage high-level signal, a source of the seventh transistor is electrically connected to the first node, and a drain of the seventh transistor is electrically connected to a gate of the ninth transistor;
wherein a source of the ninth transistor is electrically connected to the third clock control terminal, and a drain of the ninth transistor is electrically connected to the first scan driving signal at the present level;
wherein one end of the first capacitor is electrically connected to the first node, and another end of the first capacitor is electrically connected to the constant-voltage low-level signal;
wherein a gate of the twenty-seventh transistor is connected to the constant-voltage high-level signal, a source of the twenty-seventh transistor is electrically connected to the third node, and a drain of the twenty-seventh transistor is electrically connected to a gate of the twenty-ninth transistor;
wherein a source of the twenty-ninth transistor is electrically connected to the third clock control terminal, and a drain of the twenty-ninth transistor is electrically connected to the second scan driving signal at the present level; and
wherein one end of the fourth capacitor is electrically connected to the third node, and another end of the fourth capacitor is electrically connected to the constant-voltage low-level signal.

6. The GOA device according to claim 4, wherein the first sub GOA unit further comprises a first sub forward-backward scanning module, and the second sub GOA unit further comprises a second sub forward-backward scanning module;
wherein the first sub forward-backward scanning module is connected to the first scanning driving signal at a previous level, a forward scanning signal, the first scanning driving signal at a next level, the backward scanning signal, and the constant-voltage low-level signal, and is electrically connected to the first node and the second node for outputting the forward scanning signal to the first node or for outputting the backward scanning signal to the first node, and outputting the constant-voltage low-level signal to the second node under control of a potential of the first node;
wherein the second sub forward-backward scanning module is connected to the second scanning driving signal at the previous level, the forward scanning signal, the second scanning driving signal of the next level, the backward scanning signal and the constant-voltage low-level signal, and is electrically connected to the third node and the fourth node for outputting the forward scanning signal to the third node, or for outputting the backward scanning signal to the third node, and outputting the constant-voltage low-level signal to the fourth node under control of the potential of the third node.

7. The GOA device according to claim 6, wherein the first sub scanning module comprises a first transistor, a second transistor, and a sixth transistor, and the second sub scanning module comprises a twenty-first transistor, a twenty-second transistor, and a twenty-sixth transistor;
wherein a gate of the first transistor is connected to the first scan driving signal at the previous level, a source of the first transistor is connected to the forward scanning signal, and a drain of the first transistor is electrically connected to the first node and a gate of the sixth transistor;
wherein a gate of the second transistor is connected to the first scan driving signal at the next level, a source of the second transistor is connected to the backward scanning signal, and a drain of the second transistor is electrically connected to the gate of the sixth transistor;
wherein a source of the sixth transistor is connected to the constant-voltage low-level signal, and a drain of the sixth transistor is electrically connected to the second node;
wherein a gate of the twenty-first transistor is connected to the second scan driving signal at the previous level, a source of the twenty-first transistor is connected to the forward scanning signal, and a drain of the twenty-first transistor electrically connected to the third node and a gate of the twenty-sixth transistor;
wherein a gate of the twenty-second transistor is connected to the second scan driving signal at the next level, a source of the twenty-second transistor is connected to the backward scanning signal, and a drain of the twenty-second transistor is electrically connected to the gate of the twenty-sixth transistor; and
wherein a source of the twenty-sixth transistor is connected to the constant-voltage low-level signal, and a drain of the twenty-sixth transistor is electrically connected to the fourth node.

8. The GOA device according to claim 6, wherein the first sub pull-down module comprises a third transistor, a fourth transistor, a fifth transistor, an eighth transistor, a tenth transistor, and a second capacitor, the second sub pull-down modules comprise a twenty-third transistor, a twenty-fourth transistor, a twenty-fifth transistor, a twenty-eighth transistor, a thirtieth transistor, and a fifth capacitor;
wherein a gate of the third transistor is connected to the forward scanning signal, a source of the third transistor is connected to the fourth clock control terminal, a gate of the fourth transistor is connected to the backward scanning signal, a source of the fourth transistor is connected to a second clock control terminal, and a drain of the third transistor and a drain of the fourth transistor are connected to a gate of the eighth transistor;
wherein a source of the eighth transistor is connected to the constant-voltage high-level signal; a drain of the eighth transistor, a gate of the fifth transistor, and a gate of the tenth transistor are electrically connected to the second node; a source of the fifth transistor and a source of the tenth transistor are connected to the constant-voltage low-level signal; a drain of the fifth transistor is electrically connected to the first node; and a drain of the tenth transistor is electrically connected to the first scan driving signal at the present level;
wherein one end of the second capacitor is electrically connected to the second node, and another end of the second capacitor is electrically connected to the constant-voltage low-level signal;
wherein a gate of the twenty-third transistor is connected to a forward scanning signal, a source of the twenty-third transistor is connected to the fourth clock control terminal, a gate of the twenty-fourth transistor is connected to the backward scanning signal, a source of the twenty-fourth transistor is connected to the second clock control terminal, a drain of the twenty-third transistor and a drain of the twenty-fourth transistor are connected to a gate of the twenty-eighth transistor;
wherein a source of the twenty-eighth transistor is connected to the constant-voltage high-level signal; a drain of the twenty-eighth transistor, a gate of the twenty-fifth transistor, and a gate of the thirtieth transistor are electrically connected to the fourth node; a source of the twenty-fifth transistor and a source of the thirtieth transistor are connected to the constant-voltage low-level signal, a drain of the twenty-fifth transistor is electrically connected to the third node; and a drain of the thirtieth transistor is electrically connected to the second scan driving signal at the present level; and
wherein one end of the fifth capacitor is electrically connected to the fourth node, and another end of the fifth capacitor is electrically connected to the constant-voltage low-level signal.

9. The GOA device according to claim 6, wherein the first sub function control module comprises an eleventh transistor, a twelfth transistor, and a thirteenth transistor, and the second sub function control module comprises a thirty-first transistor, a thirty-second transistor, and a thirty-third transistor;
wherein a source and of the eleventh transistor, a gate of the eleventh transistor, and a gate of the twelfth transistor are connected to the first function control signal, a drain of the eleventh transistor and a drain of the thirteenth transistor are connected to the first scan driving signal at the present level, a source of the twelfth transistor and a source of the thirteenth transistor are connected to the constant-voltage low-level signal, a drain of the twelfth transistor is electrically connected to the second node, and a gate of the thirteenth transistor is connected to the second function control signal;
wherein a source of the thirty-first transistor, a gate of the thirty-first transistor, and a gate of the thirty-second transistor are connected to the fourth function control signal, a drain of the thirty-first transistor and a drain of the thirty-third transistor are connected to the second scan driving signal at the present level, a source of the thirty-second transistor and a source of the thirty-third transistor are connected to the constant-voltage low-level signal, a drain of the thirty-second transistor is electrically connected to the fourth node, and a gate of the thirty-third transistor is connected to the fifth function control signal.

10. The GOA device according to claim 4, wherein the first sub GOA unit and the second sub GOA unit comprise a turn-on functional phase and a turn-off functional phase;
in response to the first sub GOA unit in the turn-on functional phase, the first function control signal is a high-level signal, and the second function control signal is a low-level signal;
in response to the first sub GOA unit in the turn-off functional phase, the first function control signal is a low-level signal and the second function control signal is a high-level signal;
in response to the second sub GOA unit in the turn-on functional phase, the fourth function control signal is a high-level signal and the fifth function control signal is a low-level signal; and
in response to the second sub GOA unit in the turn-off functional phase, the fourth function control signal is a low-level signal and the fifth function control signal is a high-level signal.

11. The GOA device according to claim 4, wherein the first sub GOA unit further comprises a third sub function control module, and the second sub GOA unit further comprises a fourth sub function control module;
wherein the third sub control module is connected to the third function control signal, the first scan driving signal at a previous level, and the constant-voltage low-level signal, the third sub control module is electrically connected to the first node and the second node for outputting the third function control signal to the first node, and for outputting the constant-voltage low-level signal to the second node under control of a potential of the first node, and for implementing the turn-off function of all the first scan driving signals of the GOA device;
wherein the fourth sub function control module is connected to a sixth function control signal, the second scan driving signal at the previous level, and the constant-voltage low-level signal; the fourth sub function control module is electrically connected to the third node for outputting the sixth function control signal to the third node, and for outputting the constant-voltage low-level signal to the fourth node under control of the potential of the third node, and for interpermeating the turn-off function of all the second scan driving signals of the GOA device.

12. The GOA device according to claim 11, wherein the third sub function control module comprises a fourteenth transistor and a fifteenth transistor, and the fourth sub function control module comprises a thirty-fourth transistor and a thirty-fifth transistor;
wherein a gate of the fourteenth transistor is connected to the first scan driving signal at the previous level, a source of the fourteenth transistor is connected to the third function control signal, and a drain of the fourteenth transistor is electrically connected to the first node and a gate of the fifteenth transistor;
wherein a gate of the fifteenth transistor is electrically connected to the first node, a source of the fifteenth transistor is connected to the constant-voltage low-level signal, and a drain of the fifteenth transistor is electrically connected to the second node;
wherein a gate of the thirty-fourth transistor is connected to the second scan driving signal at the previous level, a source of the thirty-fourth transistor is connected to the sixth function control signal, and a drain of the thirty-fourth transistor is electrically connected to the third node and a gate of the thirty-fifth transistor; and
wherein a gate of the thirty-fifth transistor is electrically connected to the third node, a source of the thirty-fifth transistor is connected to the constant-voltage low-level signal, and a drain of the thirty-fifth transistor is electrically connected to the fourth node.

13. The GOA device according to claim 11, wherein the first sub pull-down module comprises a sixteenth transistor, a seventeenth transistor, an eighteenth transistor, and a third capacitor, and the second sub pull-down module comprises a thirty-sixth transistor, a thirty-seventh transistor, a thirty-eighth transistor, and a sixth capacitor;
wherein a gate of the sixteenth transistor is electrically connected to the second node, a source of the sixteenth transistor is connected to the constant-voltage low-level signal; a drain of the sixteenth transistor is electrically connected to the first node; a gate of the seventeenth transistor is connected to the clock signal at the next level; a source of the seventeenth transistor is connected to the first function control signal; a drain of the seventeenth transistor is electrically connected to the second node; a gate of the eighteenth transistor is electrically connected to the second node; a source of the eighteenth transistor is connected to the constant-voltage low-level signal; a drain of the eighteenth transistor is electrically connected to the first scan driving signal at the present level; one end of the third capacitor is electrically connected to the second node; and another end of the third capacitor is electrically connected to the constant-voltage low-level signal;
wherein a gate of the thirty-sixth transistor is electrically connected to the fourth node, a source of the thirty-sixth transistor is connected to the constant-voltage low-level signal; a drain of the thirty-sixth transistor is electrically connected to the third node; a gate of the thirty-seventh transistor is connected to the clock signal at the next level; a source of the thirty-seventh transistor is connected to the fourth function control signal; a drain of the thirty-seventh transistor is electrically connected to the fourth node; a gate of the thirty-eighth transistor is electrically connected to the fourth node; a source of the thirty-eighth transistor is connected to the constant-voltage low-level signal; a drain of the eighteenth transistor is electrically connected to the second scan driving signal at the present level; one end of the sixth capacitor is electrically connected to the fourth node; and another end of the sixth capacitor is electrically connected to the constant-voltage low-level signal.

14. The GOA device according to claim 11, wherein the first sub function control module comprises a seventeenth transistor and a nineteenth transistor, and the second sub function control module comprises a thirty-seventh transistor and a thirty-nineth transistor;
wherein a gate of the nineteenth transistor is connected to the second function control signal, a source of the nineteenth transistor is connected to the constant-voltage low-level signal, and a drain of the nineteenth transistor is connected to the first scan driving signal at the present level; and
wherein a gate of the thirty-ninth transistor is connected to the fifth function control signal, a source of the thirty-ninth transistor is connected to the constant-voltage low-level signal, and a drain of the thirty-ninth transistor is connected to the second scan driving signal at the present level.

15. The GOA device according to claim 4, wherein the GOA device receives a first clock signal, a second clock signal, a third clock signal, and a fourth clock signal; and
wherein the first clock signal, the second clock signal, the third clock signal, and the fourth clock signal are valid in sequence within a time division of an action cycle of the GOA device.

16. A display panel, comprising a GOA device and a functional display layer on the GOA device.

17. The display panel according to claim 16, further comprising a fingerprint recognition GOA circuit;
wherein a first sub GOA unit of the GOA device is configured to output a first scan driving signal to implement normal display of the display panel; and
wherein the second sub GOA unit of the GOA device is configured to output a second scan driving signal and control a reset function and/or a reading function of the fingerprint recognition GOA circuit to implement a fingerprint recognition function of the display panel.

18. The display panel according to claim 17, wherein the second sub GOA unit simultaneously controls the reset function and/or the reading function of multiple rows of the fingerprint recognition GOA circuit.

19. The display panel according to claim 16, wherein the second sub GOA unit of the GOA device is positioned on a side of the GOA device close to display area.

20. The display panel according to claim 16, comprising a display area, wherein the GOA device comprises an odd-level cascaded GOA sub circuit and an even-level cascaded GOA sub circuit; and
wherein the odd-level cascaded GOA sub circuit and the even-level cascaded GOA sub circuit are positioned on both sides of the display area.
